(19) United States
(12) Patent Application Publication
(10) Pub. No.: US 2024/0184953 A1
(43) Pub. Date: Jun. 6, 2024

(54) DEVICE HAVING A DIGITAL TWIN OF AN ELECTRONIC COMPONENT, METHOD FOR PRODUCING THE DEVICE HAVING THE DIGITAL TWIN, METHOD FOR DETERMINING A REPROCESSING PROCESS FOR THE COMPONENT, AND METHOD FOR REPROCESSING THE ELECTRONIC COMPONENT

(71) Applicant: Siemens Aktiengesellschaft, München (DE)

(72) Inventors: Martin Franke, Berlin (DE); Herbert Taucher, Wien (AT); Philipp Wolfrum, München (DE)

(21) Appl. No.: 18/553,635

(22) PCT Filed: Mar. 17, 2022
(86) PCT No.: PCT/EP2022/057084

§ 371 Date: Oct. 2, 2023

(30) Foreign Application Priority Data
Apr. 6, 2021 (EP) 21166905.6

(51) Int. Cl. G06F 30/20; G06Q 10/0875

(52) U.S. Cl. CPC G06F 30/20; G06Q 10/0875

(57) ABSTRACT

A device having a digital twin of an electronic component includes at least one data medium having reprocessing data regarding the component and at least one processor for processing the reprocessing data. The reprocessing data can include current reprocessing data. It is thus possible to determine a recycling (reprocessing) process which respects a specific relevant basic condition (e.g., legislation, raw material prices, etc.). The electronic component is reprocessed optimally, from ecological and economical perspectives.

### CROSS-REFERENCE TO RELATED APPLICATIONS

This application claims priority to PCT Application No. PCT/EP2022/057084, having a filing date of Mar. 17, 2022, which claims priority to EP Application No. 21166905.6, having a filing date of Apr. 6, 2021, the entire contents both of which are hereby incorporated by reference.

### FIELD OF TECHNOLOGY

The following relates to a device having a digital twin of an electronic component (assembly), to a method for producing the device having the digital twin and to a method of using the digital twin to determine a reprocessing process for the component. In addition, a method for reprocessing the electronic component is specified.

### BACKGROUND

Reprocessing (recycling) of electronic components may be useful for ecological and economic reasons. Among other things, the value (price) and the toxicity of the materials processed in the component play a decisive role here.

According to the conventional art, electronics or electronic components are usually shredded and further treated thermally and chemically so that individual materials (e.g. metals) can be recovered. Disassembling into individual elements (electronics elements or component elements) is usually not carried out without mechanical destruction. Consequently, a large part of the materials are lost.

### SUMMARY

An aspect relates to illustrate how an electronic component can be reprocessed in an efficient manner.

To achieve the aspect, a device having a digital twin of an electronic component is specified, wherein the device has at least one data medium having reprocessing data regarding the component and at least one processor for processing the reprocessing data.

To achieve the aspect, a method for producing a device having a digital twin is also specified, wherein the reprocessing data are provided.

The digital twin (digital double) of the electronic component is a digital representation or a digital image of the electronic component. In this case, the electronic component may be complex, i.e., the electronic component is made up of a plurality of component elements. It has a plurality of component elements.

In addition, to achieve the aspect, a method of using the device having the digital twin to determine a reprocessing process of an electronic component is specified, wherein the following work steps are carried out:
a) analyzing the reprocessing data of the data medium and
b) using the analysis to determine the reprocessing process (4002), wherein the processor is used to analyze the reprocessing data and/or determine the reprocessing process.

According to a further aspect of embodiments of the invention, a method for reprocessing an electronic component is specified, wherein the following work steps are carried out:
a′) using the device having the digital twin to select the reprocessing process and
b′) carrying out the reprocessing process.

The data medium serves as a data source for the reprocessing data. The data source provides the reprocessing data.

The data medium is a data memory. The reprocessing data are permanently stored in the data memory.

The reprocessing data comprise information pertaining to the reprocessing of the electronic component or pertaining to the reprocessing of component elements of the electronic component.

The processor (programmable arithmetic unit) can be used to read and process the reprocessing data of the data medium.

The concept on which embodiments of the invention are based consists in providing a digital twin (digital model) of an electronic component, which digital twin comprises information pertaining to the reprocessing of the component or pertaining to the reprocessing of component elements (parts) of the electronic component. The reprocessing data can then be used for reprocessing the component.

The reprocessing data can comprise any information of significance for reprocessing the component. According to one particular configuration, the reprocessing data comprise information pertaining to at least one group member selected from the following group:
bill of materials (BOM) of the electronic component,
work steps for manufacturing the electronic component,
prices (e.g., purchase prices) of raw materials used to manufacture the component,
possible reprocessing methods for the electronic component and
legal requirements for reprocessing the electronic component.

In this case, it is also possible to take into consideration the fact that this information may differ from country to country and/or may change over time. The reprocessing data may comprise dynamically changing information relating to local circumstances.

As mentioned, the reprocessing data can be permanently stored in a data memory. In particular, however, the reprocessing data comprise up-to-date reprocessing data. Up-to-date reprocessing data are thus provided. In order that the reprocessing data are up-to-date (e.g. country-specific and/or current on that particular day), the device, according to a further configuration, is equipped with a data interface for providing the reprocessing data of the data medium. (Chronologically and locally) up-to-date reprocessing data can be input (wirelessly or in a wired manner) via the data interface and thereby provided to the processor for processing. It is thus possible to select the reprocessing process for the electronic component on the basis of current prices of the used materials on that particular day (e.g., raw material prices of the materials). It is thus also possible to take into consideration changes in legislation when selecting the reprocessing process.

The device having the digital twin of the device can be produced after the electronic component has been designed, e.g., during a subsequent product-life phase of the electronic component. The reprocessing data are subsequently provided (once or repeatedly). Advantageously, the digital twin of the device is produced while the electronic component is being designed. A reprocessing strategy for the electronic component is thereby already available at the end of the design phase and so preparatory measures for reprocessing the electronic component can be taken.

In particular, the method of the reprocessing process is carried out repeatedly. This makes it possible, e.g., by using the digital twin, to influence the designing of the electronic component (e.g. in an iterative method in which the analysis of the reprocessing data and the determination of the reprocessing process are carried out repeatedly).

With regard to the method for determining a reprocessing process, a single reprocessing process is set (defined) in an automatic manner. However, the method can also be used to propose a selection of a plurality of reprocessing processes. The appropriate reprocessing process can then in turn be selected from the selection automatically or else manually by an operator.

In one particular configuration, at least one item of information selected from the following group is evaluated for analyzing the reprocessing data:
information pertaining to the general feasibility of the reprocessing of the component,
information pertaining to expenditure and/or costs of the reprocessing of the component,
information pertaining to legal requirements for the reprocessing of the component,
information pertaining to the extent of the reprocessing of the component,
information pertaining to possible reprocessing processes,
information about costs of the reprocessing of the component and
information pertaining to the profit that can be expected as a result of the reprocessing of the component.

The information pertaining to the general feasibility of the reprocessing of the component comprises, e.g., information pertaining to how easily the component can be disassembled. Information pertaining to legal requirements for reprocessing the component (or component elements of the component) in particular relates to local, current laws and case law in this respect. For example, limits for the contamination of the environment as a result of the reprocessing of the component are regulated by law.

Information pertaining to expenditure and/or costs of the reprocessing of the component and information pertaining to the profit that can be expected as a result of the reprocessing relate to economical factors of the reprocessing or economical factors of various, possible (potential) reprocessing processes.

In one particular configuration, at least one mathematical optimization method is used for analyzing the reprocessing data and/or for determining the reprocessing process.

In summary, the following advantages are associated with embodiments of the invention:
Embodiments of the invention make it possible to select a reprocessing process that is appropriate (favorable) from ecological and economical perspectives.
The use of permanently predefined standard reprocessing processes can be avoided. Embodiments of the invention are characterized by high flexibility. It is possible to react to given circumstances (e.g., current laws) and changes thereto individually and quickly.
Existing reprocessing resources (means for reprocessing components) can be used.
The reprocessing of an electronic component is already taken into consideration while the electronic component is being designed. Preparations for the reprocessing of the electronic component can thus be made in good time.
An electronic component is designed from an ecological perspective. The need for sustainability when designing an electronic component is thereby taken into account.
In addition to sustainability, economical viability with regard to possible reprocessing processes of the component is taken into consideration.
The basic reprocessability (recyclability) of the electronic component is already taken into consideration while it is being designed.
It is also possible to determine a specific procedure for the dismantling/reprocessing process for the electronic component during the design phase.
The ease with which an electronic component can be dismantled and recycled greatly depends on the design of the electronic component, which would not be readily identifiable without precise knowledge of the component. The digital twin is a model of the electronic component and provides precisely this knowledge.
The digital twin allows an electronic component to be disassembled in a manner that is optimized for the respective design in order to recover a maximum amount of the raw materials contained.

### BRIEF DESCRIPTION

Some of the embodiments will be described in detail, with reference to the following figures, wherein like designations denote like members, wherein:

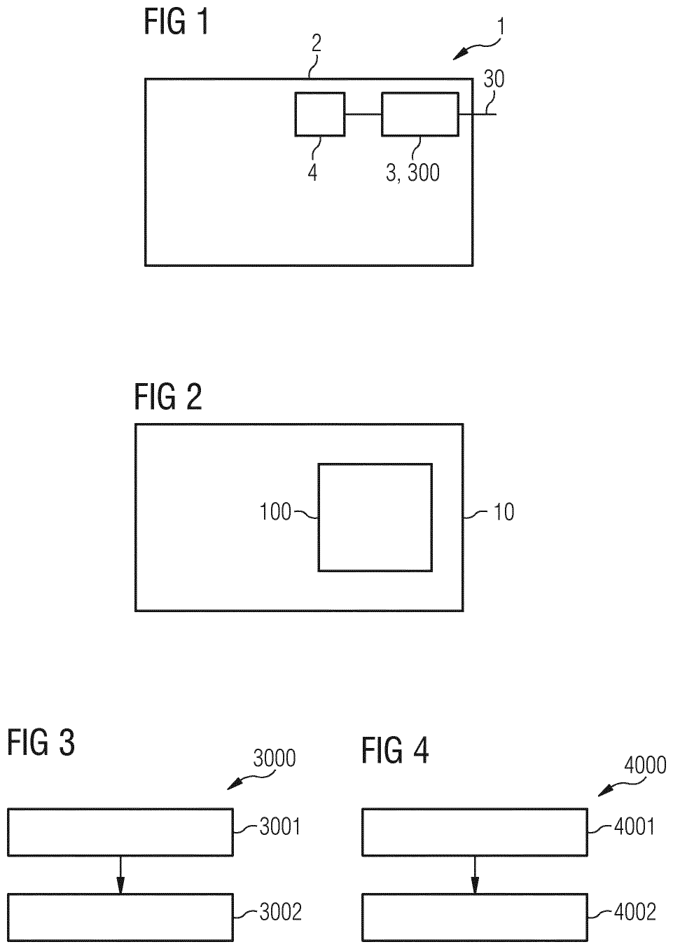

FIG. 1 shows a device having a digital twin;

FIG. 2 shows an electronic component;

FIG. 3 shows a method for determining a reprocessing process of an electronic component; and

FIG. 4 shows a method for reprocessing an electronic component.

### DETAILED DESCRIPTION

The aim of the exemplary embodiment is to determine a reprocessing process that is tailored to the electronic component 10 or to the component element 100 of the electronic component 10.

The starting point for this is a device 1 having a digital twin 2 of the electronic component 10 or of the component element 100 of the electronic component 10. The device 1 has a data medium 3 having reprocessing data 300 regarding the component 10. The data medium 3 is a data memory. The device 1 has a processor 4 for processing the reprocessing data 300.

The reprocessing data 300 are up-to-date reprocessing data (current on that particular day) which are provided wirelessly via the data interface 30. The reprocessing data 300 contain the following data:
bill of materials of the electronic component 10,
work steps for manufacturing the electronic component 10,
prices of raw materials used to manufacture the component 10,
possible reprocessing methods for the electronic component 10 and
legal requirements for reprocessing the electronic component 10.

For the subsequent reprocessing of the electronic component 10, the digital twin 2 is produced already while the electronic component 10 is being designed.

Using the device 1 having the digital twin 2, a method 3000 for determining a reprocessing process 4002 for the electronic component 10 imaged by the digital twin 2 is carried out with the following procedure:
a) step 3001: analyzing the reprocessing data 300 of the data medium 3 and
b) step 3002: using the analysis to determine the reprocessing process 4002, wherein
the processor 4 is used to analyze 3001 the reprocessing data 300 and/or to determine 3002 the reprocessing process 4002.

The reprocessing process is determined afterward on the basis of reprocessing data that are current on that particular day. In an alternative embodiment, the reprocessing process is already determined during or after the design phase of the electronic component 10. For this purpose, use is then made of reprocessing data that are not current on that particular day.

For the step 3001 (analyzing the reprocessing data 300 of the data medium 3), the following information is evaluated:
information pertaining to the general feasibility of the reprocessing of the component 10,
information pertaining to expenditure and/or costs of the reprocessing of the component 10,
information pertaining to legal requirements for the reprocessing of the component 10,
information pertaining to the extent of the reprocessing of the component 10,
information pertaining to possible reprocessing processes for the component 10,
information about costs of the reprocessing of the component 10 and
information pertaining to the profit that can be expected as a result of the reprocessing of the component 10.

Finally, the electronic component 10 is reprocessed by way of the following work steps:
a′) using the device 1 having the digital twin 2 to select (4001) the reprocessing process (4002) and
b′) carrying out the reprocessing process (4002).

The selection 4001 of the reprocessing process 4002 of the electronic component 10 is described in more detail below.

For the electronic component 10 having the design D and all the considered recycling methods mᵢ(i=1 . . . N), the following functions are provided:
A Boolean function R(D,mᵢ) which specifies whether the reprocessing process (recycling method) mᵢ is technically able to disassemble the electronic component 10 and if so whether all the legal requirements (regulations) are met (indicated by “1”) or are not met (indicated by “0”).
A scalar function C_{rec}(D,mᵢ) which specifies the costs/the expenditure of the disassembly using the reprocessing process mᵢ. For R(D,mᵢ)=0, C_{rec}(D,mᵢ)=∞ is defined. This function also contains any possible additional costs which arise due to legal obligations for the selected reprocessing process mᵢ.
A one-dimensional or multi-dimensional function V_{rec}(D,mᵢ) which reflects the extent of the recycling and the value of the recovered elements and materials.
A scalar function V_{tot,rec}(D,mᵢ)=f(V_{rec}(D,mᵢ))−C_{rec}(D,mᵢ) as the overall benefit of the reprocessing process mᵢ. This aggregates the possibly multi-dimensional function V_{rec}(D,mᵢ) to form one scalar value f(V_{rec}(D,mᵢ)) which represents the benefit of the reprocessing process mᵢ, and deducts the costs C_{rec}(D,mᵢ) therefrom. This function can be negative if the reprocessing expenditure exceeds the value of the materials resulting from the reprocessing process.

Moreover, a mathematical optimization method is then applied, which, from all the reprocessing processes mᵢ, selects the one that maximizes the overall benefit:

$$i = {arg max}_{i = 1 .. N} ( {V}_{tot , rec} ( D , {m}_{i} ) )$$

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A device having a digital twin of an electronic component, wherein the device has
at least one data medium having reprocessing data regarding the component and
at least one processor for processing the reprocessing data.

2. The device as claimed in claim 1, wherein the data medium is a data memory.

3. The device as claimed in claim 1, wherein the reprocessing data comprise information pertaining to at least one group member selected from the following group:
bill of materials of the electronic component,
work steps for manufacturing the electronic component,
prices of raw materials used to manufacture the component,
possible reprocessing methods for the electronic component and
legal requirements for reprocessing the electronic component.

4. The device as claimed in claim 1, wherein the reprocessing data comprise up-to-date reprocessing data.

5. The device as claimed in claim 1, wherein the device is equipped with a data interface for providing the reprocessing data of the data medium.

6. A method for producing a device having the digital twin as claimed in claim 1, wherein the reprocessing data are provided.

7. The method as claimed in claim 6, wherein the digital twin of the device is produced while the electronic component is being designed.

8. A method of using the device having a digital twin as claimed in claim 1 to determine a reprocessing process of an electronic component, wherein the following work steps are carried out:
a) analyzing the reprocessing data of the data medium and
b) using the analysis to determine the reprocessing process, wherein
the processor is used to analyze the reprocessing data and/or determine the reprocessing process.

9. The method as claimed in claim 8, wherein the method is carried out repeatedly.

10. The method as claimed in claim 8, wherein the reprocessing process is determined while the electronic component is being designed.

11. The method as claimed in claim 8, wherein up-to-date reprocessing data are provided for analyzing the reprocessing data.

12. The method as claimed in claim 8, wherein at least one item of information selected from the following group is evaluated for analyzing the reprocessing data:
information pertaining to the general feasibility of the reprocessing of the component,
information pertaining to expenditure and/or costs of the reprocessing of the component,
information pertaining to legal requirements for the reprocessing of the component,
information pertaining to the extent of the reprocessing of the component,
information pertaining to possible reprocessing processes for the component,
information about costs of the reprocessing of the component and
information pertaining to the profit that is expected as a result of the reprocessing of the component.

13. The method as claimed in claim 8, wherein at least one mathematical optimization method is used for analyzing the reprocessing data and/or for determining the reprocessing process.

14. A method for reprocessing an electronic component, wherein the following work steps are carried out:
a′) using the device having a digital twin as claimed in claim 1 to select the reprocessing process and
b′) carrying out the reprocessing process.
